(19) United States
(12) Patent Application Publication
(10) Pub. No.: US 2026/0342050 A1
(43) Pub. Date: Oct. 29, 2026

(54) METHOD OF MAKING LOW-POWER CONSUMPTION QUANTUM CASCADE LASER

(71) Applicant: CHANGCHUN INSTITUTE OF OPTICS, FINE MECHANICS AND PHYSICS, CHINESE ACADEMY OF SCIENCES, CHANGCHUN (CN)

(72) Inventors: Bo MENG, CHANGCHUN (CN); Lequan ZHANG, CHANGCHUN (CN); Peng LIU, CHANGCHUN (CN); Cunzhu TONG, CHANGCHUN (CN)

(73) Assignee: CHANGCHUN INSTITUTE OF OPTICS, FINE MECHANICS AND PHYSICS, CHINESE ACADEMY OF SCIENCES, CHANGCHUN (CN)

(21) Appl. No.: 19/659,167

(22) Filed: Apr. 27, 2026

(30) Foreign Application Priority Data
Apr. 27, 2025 (CN) 202510540578.4

(51) Int. Cl. H01S 5/34; H01S 5/20; H01S 5/22

(52) U.S. Cl. CPC H01S 5/3402; H01S 5/2018; H01S 5/22; H01S 2302/00

(57) ABSTRACT

A preparation method of a low-power consumption mid-infrared quantum cascade laser. The method includes: providing, an epitaxial wafer, wherein the epitaxial wafer includes an initial lower waveguide layer, an active layer and an initial upper waveguide layer stacked in sequence; performing, a patterning process on a partial thickness of the epitaxial wafer to form a substrate and an initial ridge structure on the substrate, the initial ridge structure having a groove on a side surface thereof, and the initial ridge structure including a lower waveguide layer, an initial active region and an upper waveguide layer stacked in sequence in a direction away from the substrate; and performing transverse etching on the initial active region through the groove to remove a partial width of the initial active region, a remaining initial active region serving as an active region.

### CROSS REFERENCE TO RELATED APPLICATION

The present application claims priority to Chinese patent application No. 202510540578.4, entitled “METHOD OF MAKING LOW-POWER CONSUMPTION QUANTUM CASCADE LASER”, filed on Apr. 27, 2025, the disclosure of which is hereby incorporated by reference in its entirety. No new matter has been introduced.

### TECHNICAL FIELD

The present disclosure relates to the technical field of lasers, and in particular to preparation method of low-power consumption mid-infrared quantum cascade laser.

### BACKGROUND

For a mid-infrared quantum cascade laser, the area of the active region is positively correlated with power consumption, and a relatively large device has a power consumption of more than ten watts, which is inconvenient for integration into portable applications. Power consumption can usually be reduced by shortening the cavity length or reducing the ridge width. From the perspective of the existing chip cleaving technology, the minimum cavity length can only reach the order of hundreds of micrometers, which is difficult to further shorten; therefore, breakthroughs can only be sought in the direction of reducing the ridge width. However, due to the limitation of contact lithography technology, the narrowest achievable ridge width of the mid-infrared quantum cascade laser at present is about 4 μm.

At present, the relevant technical solutions for preparing low-power consumption mid-infrared quantum cascade lasers include the following methods: the first is a method for reducing power consumption through a buried heterostructure, which requires etching all cladding layers above the active region of an epitaxial wafer with an etchant, forming a lithographic structure on the active region, and undergoing multiple regrowth processes; the second is preparing narrow-ridge devices by exposure with precision equipment; the third is shortening the cavity length to further reduce the area of the active region so as to achieve low power consumption. The above methods have the following disadvantages: the buried heterostructure requires regrowth, which not only complicates the process, but also results in extremely high preparation cost and insufficient stability of the preparation process, the epitaxial growth conditions are harsh, and the uniformity of the active region is difficult to control; precision electron beam lithography equipment is extremely expensive and few in quantity, which requires complex processes and long exposure time (the exposure time can even reach one week), and is easily disturbed by external vibration, which affects the exposure effect; the shortening of the cavity length is limited by chip cleaving equipment, and the minimum cavity length can only reach the order of hundreds of micrometers.

### SUMMARY

In view of this, the present disclosure is intended to provide a preparation method of a low-power consumption mid-infrared quantum cascade laser, which is at least conducive to reducing the preparation difficulty of a quantum cascade laser with a narrow ridge.

To achieve the above objectives, the technical solution of the present disclosure is implemented as follows.

The disclosure provides a preparation method of a low-power consumption mid-infrared quantum cascade laser. The method comprises: providing, an epitaxial wafer, wherein the epitaxial wafer includes an initial lower waveguide layer, an active layer and an initial upper waveguide layer stacked in sequence; performing, a patterning process on a partial thickness of the epitaxial wafer to form a substrate and an initial ridge structure on the substrate, the initial ridge structure having a groove on a side surface thereof, and the initial ridge structure including a lower waveguide layer, an initial active region and an upper waveguide layer stacked in sequence in a direction away from the substrate; and performing, transverse etching on the initial active region through the groove to remove a partial width of the initial active region, a remaining initial active region serving as an active region, a width of the upper waveguide layer and a width of the lower waveguide layer being both greater than a width of the active region, and the lower waveguide layer, the active region and the upper waveguide layer forming a ridge structure.

Further, forming, the initial ridge structure comprises: forming, a mask layer with a first etching window on the initial upper waveguide layer of the epitaxial wafer, the mask layer corresponding to the initial ridge structure; etching, the epitaxial wafer through the first etching window to form the groove and the initial ridge structure; and removing, the mask layer.

Further, a process method for etching the epitaxial wafer includes at least one of a dry etching process and a wet etching process.

Further, forming, the mask layer comprises:
forming, an initial mask layer on the epitaxial wafer; forming, a first photoresist layer on the initial mask layer, and performing, exposure and development on the first photoresist layer to transfer a pattern of a photomask onto the first photoresist layer; etching, using the first photoresist layer as a mask, the initial mask layer unprotected by the first photoresist layer, to transfer the pattern onto the initial mask layer, to form the mask layer; and removing, the first photoresist layer.

Further, performing, transverse etching on the initial active region through the groove comprises: performing, selective etching on the initial active region, using a first etching solution, to form a narrower active region.

Further, after forming the ridge structure, the method further comprises: forming, an insulating layer on the ridge structure and the substrate; removing, the insulating layer on a top surface of the upper waveguide layer; and forming, a first electrode on the remaining insulating layer and the top surface of the upper waveguide layer.

Further, removing the insulating layer on the top surface of the upper waveguide layer comprises: forming, a second photoresist layer with a second etching window on the insulating layer after forming the insulating layer, the second etching window being aligned with the upper waveguide layer; removing, the insulating layer on the top surface of the upper waveguide layer through the second etching window; and removing, the second photoresist layer.

Further, after forming the first electrode, the method further comprises: thinning, a side of the substrate away from the first electrode; and forming, a second electrode on a bottom surface of the thinned substrate.

Further, a height of the ridge structure is in a range of 7 μm to 10 μm.

Compared with the prior art, the present disclosure can achieve the following beneficial effects: to further reduce the ridge width and thus the device power consumption, the present disclosure proposes a process scheme for preparing a mid-infrared quantum cascade laser with an ultra-narrow ridge width by selectively etching the active region, which can effectively avoid the preparation of narrow-ridge devices by adopting complex processes and effectively save time and economic costs. It should be noted that the preparation time of the method for preparing a low-power consumption mid-infrared quantum cascade laser provided by the present disclosure is close to that of a conventional process for preparing a ridge waveguide; therefore, the time cost can be effectively saved, and the etching rate for forming the active region is controllable, resulting in a high yield of devices.

### BRIEF DESCRIPTION OF DRAWINGS

The drawings form a part of the present disclosure, are provided to further understand the present disclosure. The schematic embodiments and descriptions thereof are used to explain the present disclosure and do not constitute an improper limitation thereof.

FIGS. 1 to 18 are schematic diagrams of each step of a preparation method of a low-power consumption mid-infrared quantum cascade laser according to an embodiment of the present disclosure.

FIG. 19 is a structural schematic diagram of a low-power consumption mid-infrared quantum cascade laser according to an embodiment of the present disclosure.

### DETAILED DESCRIPTION

To make the objectives, technical solutions, and advantages of the present disclosure clearer, the present disclosure will be further described in detail below with reference to the drawings and specific embodiments. It should be understood that the specific embodiments described herein are only for explaining the present disclosure and do not constitute a limitation on the present disclosure.

It should be noted that, without conflict, the embodiments of the present disclosure and the features in the embodiments can be combined with each other.

In the description of the present invention, it should be understood that the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise” indicate the orientation or position relationship based on the orientation or position relationship shown in the drawings, which is only for the convenience of describing the present invention and simplifying the description, rather than indicating or implying that the device or element referred to must have a specific orientation, be constructed and operated in a specific orientation, and therefore cannot be understood as a limitation of the present invention. In addition, in the present invention, the descriptions such as “first”, “second”, etc. are only used for descriptive purposes and cannot be understood as indicating or implying their relative importance or implicitly indicating the number of technical features indicated. Thus, the features defined as “first” and “second” may explicitly or implicitly include one or more features. In the description of the present invention, the meaning of “a plurality of” is two or more, unless otherwise clearly and specifically defined.

In the description of the disclosure, it should be noted that unless otherwise clearly specified and limited, the terms “mount”, “connected” and “connect” should be understood in a broad sense, for example, it can be a fixed connection, a detachable connection, or an integral connection, and can be a mechanical connection, an electrical connection. It can be directly connected, indirectly connected by an intermediate medium, and an internal connection of two elements. For those skilled in the art, the specific meanings of the above-mentioned terms in the disclosure can be understood according to the specific circumstances.

The present disclosure will be described in detail below with reference to the drawings and embodiments.

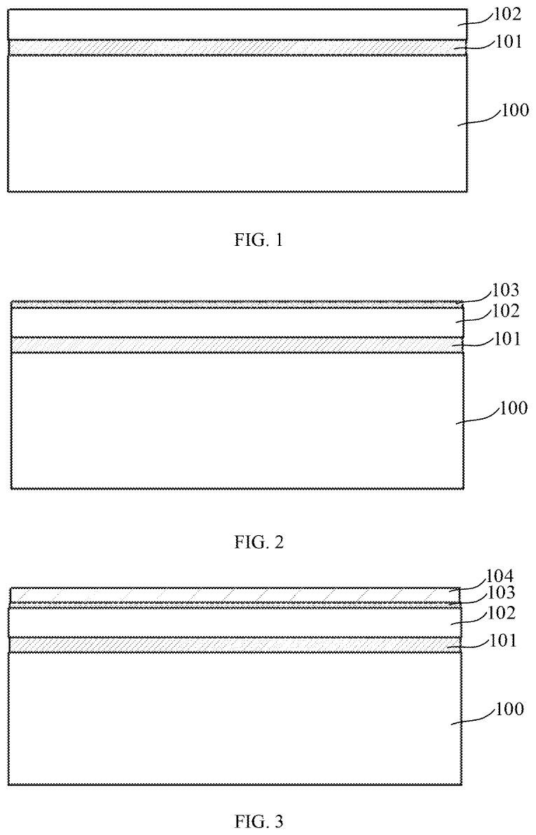

As shown in FIGS. 1 to 18, the disclosure provides a preparation method of a low-power consumption mid-infrared quantum cascade laser, comprising: providing, an epitaxial wafer, wherein the epitaxial wafer includes an initial lower waveguide layer 110, an active layer 101 and an initial upper waveguide layer 102 stacked in sequence, as shown in FIG. 1; and as shown in FIG. 8, performing, a patterning process on a partial thickness of the epitaxial wafer to form a substrate 110 and an initial ridge structure on the substrate 110, the initial ridge structure having a groove on a side surface thereof, and the initial ridge structure including a lower waveguide layer 120, an initial active region 111 and an upper waveguide layer 112 stacked in sequence in a direction away from the substrate. The initial lower waveguide layer 100 is used to form the substrate 110 and the lower waveguide layer 120, the active layer 101 is used to form the active region 121, and the initial lower waveguide layer 100 is used to form the lower waveguide layer 120.

In some embodiments, the material of the lower waveguide layer 120 includes N-type doped InP, and the doping material thereof may be Si.

In some embodiments, the material of the active layer 101 includes InGaAs or InAlAs. In some embodiments, the thickness of the active layer 101 may be in a range of 1 μm to 3 μm.

In some embodiments, the material of the upper waveguide layer 112 includes N-type doped InP, and the doping material thereof may be Si.

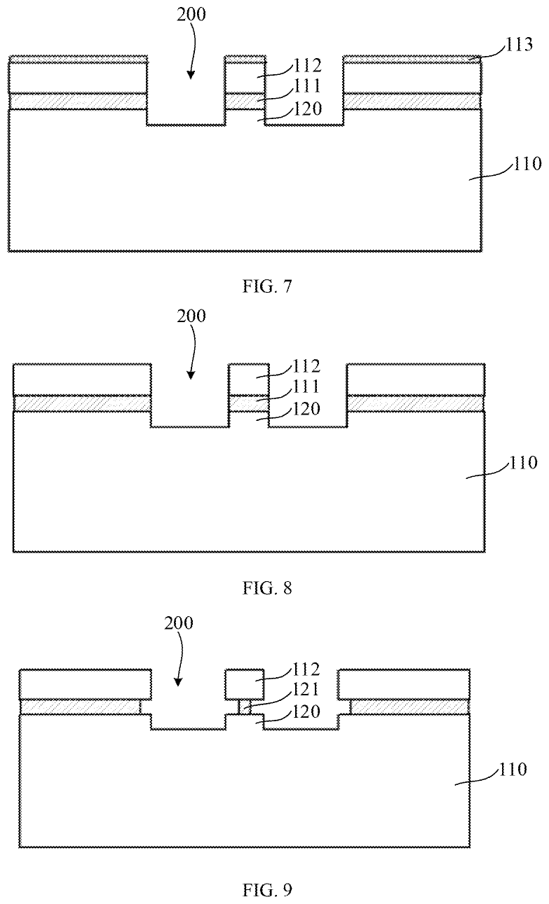

In some embodiments, the specific steps of forming the initial ridge structure include: as shown in FIG. 6, forming a mask layer 113 with a first etching window 123 on the initial upper waveguide layer 102 of the epitaxial wafer, the mask layer 113 corresponding to the initial ridge structure to be formed subsequently; as shown in FIG. 7, etching the epitaxial wafer through the first etching window 123 to form the groove 200 and the initial ridge structure; as shown in FIG. 8, then removing the mask layer 113.

In some embodiments, the mask layer 113 may be a hard mask layer, and the material of the hard mask layer may be at least one of silicon oxide, silicon nitride and silicon oxynitride.

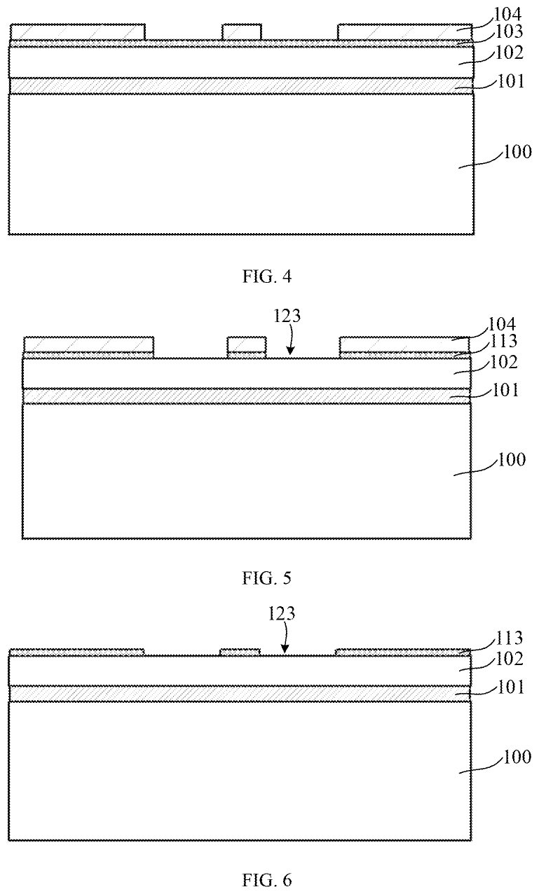

In some embodiments, as shown in FIGS. 2 to 6, forming, the mask layer 113 comprises: as shown in FIG. 2, forming, an initial mask layer 103 on the epitaxial wafer; forming, as shown in FIGS. 3 and 4, a first photoresist layer 104 on the initial mask layer 103, and performing, exposure and development on the first photoresist layer 104 to transfer a pattern of a photomask onto the first photoresist layer 104; as shown in FIG. 5, etching, using the first photoresist layer 104 as a mask, the initial mask layer 103 unprotected by the first photoresist layer 104, to transfer the pattern onto the initial mask layer 103, to form the mask layer 113; and as shown in FIG. 6, removing, the first photoresist layer 104.

In some embodiments, the pattern of the photomask may specifically be a double-groove ridge pattern, a single-ridge pattern, an annular pattern corresponding to a ring cavity structure laser, or a ridge structure pattern corresponding to a distributed feedback waveguide structure laser, etc. It should be noted that the drawings provided in the embodiments of the present disclosure are illustrated by taking the ridge structure as a double-groove ridge structure as an example, and thus, correspondingly, the pattern of the photomask is a double-groove ridge pattern.

In some examples, the process method for forming the initial mask layer 103 may be at least one of plasma enhanced chemical vapor deposition, chemical vapor deposition, atomic layer deposition, molecular layer deposition, electron beam evaporation and magnetron sputtering.

In some examples, the thickness of the initial mask layer 103 may be any thickness value in the range of 500 nm to 1 μm.

In some examples, the method of etching the initial mask layer 103 using the first photoresist layer 104 as a mask may be at least one of a dry etching process and a wet etching process.

In some embodiments, the process method for etching the epitaxial wafer includes at least one of a dry etching process and a wet etching process.

In some embodiments, an etchant with a high etching rate for the mask layer 113 may be used to remove the mask layer 113. Specifically, in some embodiments, a buffered oxide etchant may be used to remove the mask layer 113. In other embodiments, a hydrofluoric acid etchant or a sodium hydroxide etchant may also be used to remove the mask layer 113.

As shown in FIGS. 8 and 9, after removing the mask layer 113, transverse etching is performed on the initial active region 111 through the groove 200 to remove a partial width of the initial active region 111, the remaining initial active region 111 serves as an active region 121, the width of the upper waveguide layer 112 and the width of the lower waveguide layer 120 are both greater than the width of the active region 121, and the lower waveguide layer 120, the active region 121 and the upper waveguide layer 112 form a ridge structure. In this way, through the high-selectivity transverse etching of the initial active region 111, an active region 121 with a narrow width can be obtained while keeping the width of the upper waveguide layer 112 unchanged, and the narrowing of the active region 121 can reduce the power consumption of the quantum cascade laser.

In other embodiments, a height of the ridge structure is in a range of 7 μm to 10 μm.

In other embodiments, performing, transverse etching on the initial active region 111 through the groove 200 comprises: performing, selective etching on the initial active region 111, using a first etching solution, to form the active region 121. In other embodiments, a dry etching process may also be used to perform selective etching on the initial active region 111.

In some embodiments, the first etching solution includes a halogen element compound.

In some embodiments, the relationship between the etching time and the etching depth of the selective etching of the initial active region 111 using the first etching solution may be as shown in Table 1, where Table 1 is as follows:

| Etching Time | 1 min | 2 min | 3 min |
|---|---|---|---|
| Etching Depth | 0.6 μm | 1.3 μm | 1.9 μm |

It can be seen from Table 1 that the etching rate is basically constant, and the change of the etching depth is nearly linear for different etching times.

In some embodiments, the etching rate of the selective etching of the initial active region 111 using the first etching solution is in the range of 0.6 μm/min to 0.63 μm/min, which not only makes the etching process more controllable, but also helps to ensure a high etching efficiency while improving the etching precision.

In some embodiments, the width of the active region 121 is in the range of 0.3 μm to 4 μm, and in some examples, the width of the active region 121 may be 0.5 μm.

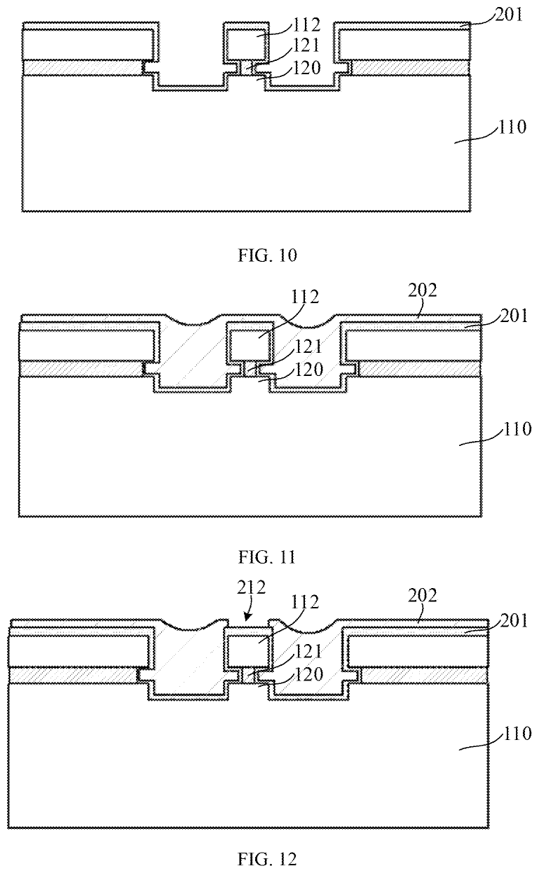

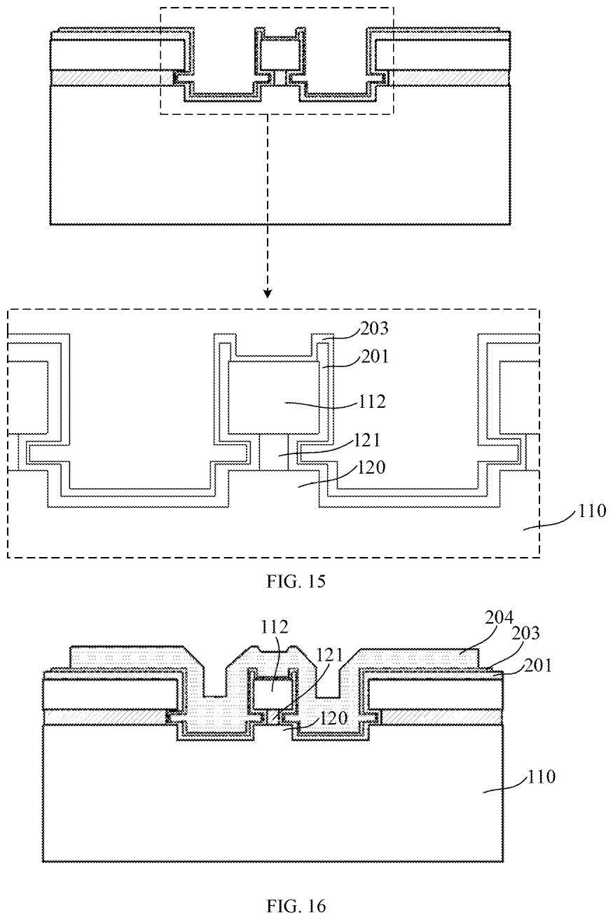

In some embodiments, after forming the ridge structure, the method further includes: as shown in FIG. 10, forming an insulating layer 201 on the ridge structure and the substrate 110, in some examples, the material of the insulating layer 201 includes at least one of silicon oxide, silicon nitride and silicon oxynitride, and the insulating layer 201 may be formed by means of plasma enhanced chemical vapor deposition, chemical vapor deposition, atomic layer deposition, molecular layer deposition, electron beam evaporation, magnetron sputtering or the like; as shown in FIG. 14, the insulating layer 201 on the top surface of the upper waveguide layer 112 needs to be removed after forming the insulating layer 201; as shown in FIG. 15, forming a first electrode 203 on the remaining insulating layer 201 and the top surface of the upper waveguide layer 112.

In some embodiments, as shown in FIG. 16, after forming the first electrode 203, the method further includes forming an electroplated gold layer 204 on the first electrode 203 through an electroplating process.

In some examples, the thickness of the insulating layer 201 may be in the range of 500 nm to 1.5 μm.

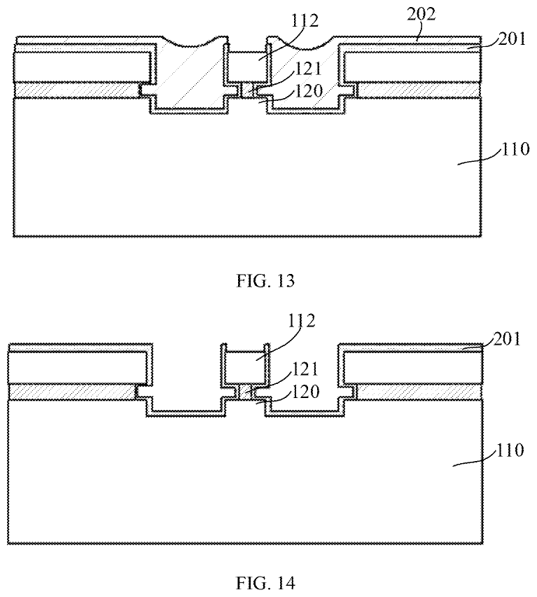

In some embodiments, the steps of removing the insulating layer 201 on the top surface of the upper waveguide layer 112 include: as shown in FIGS. 11 and 12, after forming the insulating layer 201, forming a second photoresist layer 202 with a second etching window 212 on the insulating layer 201, the second etching window 212 being aligned with the upper waveguide layer 112; as shown in FIG. 13, removing the insulating layer 201 on the top surface of the upper waveguide layer 112 through the second etching window 212; as shown in FIG. 14, removing the second photoresist layer 202.

In some embodiments, at least one of a dry etching process and a wet etching process may be used to remove the insulating layer 201 on the top surface of the upper waveguide layer 112.

In some embodiments, the method of forming the first electrode 203 may be at least one of magnetron sputtering, electron beam deposition and electroplating. In some examples, the material of the first electrode 203 may include Ti and Au, and in other examples, the material of the first electrode 203 may include Ti, Pt and Au.

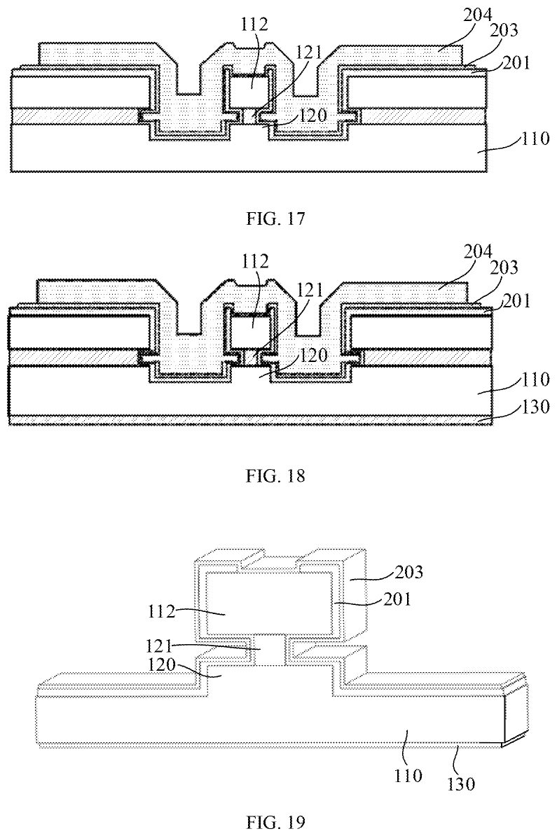

In some embodiments, after forming the first electrode 203, the method further includes: as shown in FIG. 17, thinning a side of the substrate 110 away from the first electrode 203; as shown in FIG. 18, forming a second electrode 130 on the bottom surface of the thinned substrate 110.

In some embodiments, the method of forming the second electrode 130 may be at least one of magnetron sputtering, electron beam deposition and electroplating. In some examples, the material of the second electrode 130 may include AuGe, Ni and Au, and in other examples, the material of the second electrode 130 may include Ni, AuGe, Ni and Au.

In some embodiments, the thickness of the thinned substrate 110 may be in the range of 100 μm to 200 μm.

A specific embodiment of the present disclosure is provided below, and the specific steps of the preparation method of the low-power consumption mid-infrared quantum cascade laser may be as follows:
Step 1: Growing one initial mask layer 103 on an indium phosphide-based epitaxial wafer by plasma enhanced chemical vapor deposition;
Step 2: Performing glue coating, exposure and development on the initial mask layer 103 of the epitaxial wafer to transfer the pattern of the photomask onto the first photoresist layer 104;
Step 3: Using the first photoresist layer 104 as a mask, dry-etching the part of the initial mask layer 103 unprotected by the first photoresist to transfer the double-channel ridge pattern onto the initial mask layer 103, i.e., forming a mask layer 113 with a first etching window 123 on the epitaxial wafer;
Step 4: Removing the photoresist from the epitaxial wafer with the first photoresist layer 104, then dry-etching the upper layer of the epitaxial wafer through the first etching window 123 to form a ridge structure;
Step 5: Removing the remaining mask layer 113 with a buffered oxide etchant (BOE, Buffered Oxide Etch);
Step 6: Etching to obtain an active region 121 with a selective etchant for the active region 121, the active region 121 having a narrow width;
Step 7: Growing an insulating layer 201 by plasma enhanced chemical vapor deposition;
Step 8: Performing glue coating, exposure and development on the epitaxial wafer with the grown insulating layer 201 to form a second photoresist layer 202 with a second etching window 212;
Step 9: Etching the insulating layer 201 at the position of the second etching window 212 by plasma inductively coupled etching, then removing the second photoresist layer 202;
Step 10: Depositing a first electrode 203 by magnetron sputtering, forming an electroplated gold layer 204 on the first electrode through an electroplating process, in some examples, the thickness of the electroplated gold layer 204 may be in the range of 3 μm to 6 μm;
Step 11: Thinning and polishing the substrate 110, depositing a second electrode 130, and performing a high-temperature annealing process to make the second electrode 130 form a good ohmic contact with the substrate 110, in some examples, the temperature of the high-temperature annealing may be in the range of 280 °C to 320 °C, and the time of the high-temperature annealing may be in the range of 30 s to 120 s;

Step 12: Performing cleaving to obtain the structure shown in FIG. 19, and packaging to obtain a low-power consumption mid-infrared quantum cascade laser.

The present disclosure avoids the preparation of narrow-ridge devices by adopting complex processes such as secondary epitaxy, and the preparation method of the low-power consumption mid-infrared quantum cascade laser provided by the present disclosure not only has low time cost and preparation cost, but also can prepare a narrower active region 121, and theoretically can even realize the preparation of an active region 121 with a width on the order of hundreds of nanometers; in addition, the etching rate for forming the active region 121 is stable, the etching depth is linear with time, the width of the active region 121 can be precisely controlled, and the repeatability is high; it has high redundancy for subsequent processes, is easy to open windows, has high compatibility with the existing conventional ridge waveguide processes, and has high process uniformity.

It should be understood that the various forms of processes shown above can be reordered, added to, or deleted from. For example, each step described in the present disclosure can be executed in parallel, sequentially, or in different orders, as long as the desired results of the technical solution in the present disclosure can be achieved, which is not limited herein.

The above-mentioned specific embodiments do not constitute a limitation on the protection scope of the present disclosure. It should be understood by those skilled in the art that various modifications, combinations, sub-combinations, and substitutions can be made according to design requirements and other factors. Any modifications, equivalent substitutions, improvements, etc. made within the spirit and principles of this disclosure shall be included within the scope of the claims of this disclosure.

What is claimed is:

1. A preparation method of a low-power consumption mid-infrared quantum cascade laser, comprising:
providing, an epitaxial wafer, wherein the epitaxial wafer includes an initial lower waveguide layer, an active layer and an initial upper waveguide layer stacked in sequence;
performing, a patterning process on a partial thickness of the epitaxial wafer to form a substrate and an initial ridge structure on the substrate, the initial ridge structure having a groove on a side surface thereof, and the initial ridge structure including a lower waveguide layer, an initial active region and an upper waveguide layer stacked in sequence in a direction away from the substrate; and
performing, transverse etching on the initial active region through the groove to remove a partial width of the initial active region, a remaining initial active region serving as an active region, a width of the upper waveguide layer and a width of the lower waveguide layer being both greater than a width of the active region, and the lower waveguide layer, the active region and the upper waveguide layer forming a ridge structure.

2. The preparation method of the low-power consumption mid-infrared quantum cascade laser according to claim 1, wherein
forming, the initial ridge structure comprises:
forming, a mask layer with a first etching window on the initial upper waveguide layer of the epitaxial wafer, the mask layer corresponding to the initial ridge structure;
etching, the epitaxial wafer through the first etching window to form the groove and the initial ridge structure; and
removing, the mask layer.

3. The preparation method of the low-power consumption mid-infrared quantum cascade laser according to claim 2, wherein
a process method for etching the epitaxial wafer includes at least one of a dry etching process and a wet etching process.

4. The preparation method of the low-power consumption mid-infrared quantum cascade laser according to claim 2, wherein
forming, the mask layer comprises:
forming, an initial mask layer on the epitaxial wafer;
forming, a first photoresist layer on the initial mask layer, and performing, exposure and development on the first photoresist layer to transfer a pattern of a photomask onto the first photoresist layer;
etching, using the first photoresist layer as a mask, the initial mask layer unprotected by the first photoresist layer, to transfer the pattern onto the initial mask layer, to form the mask layer; and
removing, the first photoresist layer.

5. The preparation method of the low-power consumption mid-infrared quantum cascade laser according to claim 1, wherein
performing, transverse etching on the initial active region through the groove comprises: performing, selective etching on the initial active region, using a first etching solution, to form the active region.

6. The preparation method of the low-power consumption mid-infrared quantum cascade laser according to claim 1, wherein
after forming the ridge structure, the method further comprises:
forming, an insulating layer on the ridge structure and the substrate;
removing, the insulating layer on a top surface of the upper waveguide layer; and
forming, a first electrode on the remaining insulating layer and the top surface of the upper waveguide layer.

7. The preparation method of the low-power consumption mid-infrared quantum cascade laser according to claim 6, wherein
after forming the first electrode, the method further comprises:
thinning, a side of the substrate away from the first electrode; and
forming, a second electrode on a bottom surface of the thinned substrate.

8. The preparation method of the low-power consumption mid-infrared quantum cascade laser according to claim 6, wherein
removing the insulating layer on the top surface of the upper waveguide layer comprises:
forming, a second photoresist layer with a second etching window on the insulating layer after forming the insulating layer, the second etching window being aligned with the upper waveguide layer;
removing, the insulating layer on the top surface of the upper waveguide layer through the second etching window; and
removing, the second photoresist layer.

9. The preparation method of the low-power consumption mid-infrared quantum cascade laser according to claim 1, wherein
a height of the ridge structure is in a range of 7 μm to 10 μm.
